(19) United States
(12) Patent Application Publication
(10) Pub. No.: US 2013/0063888 A1
(43) Pub. Date: Mar. 14, 2013

(54) SERVER RACK SYSTEM

(71) Applicant: Shi-Feng Wang, Shanghai City (CN)

(72) Inventor: Shi-Feng Wang, Shanghai City (CN)

(73) Assignee: INVENTEC CORPORATION, Taipei City (TW)

(21) Appl. No.: 13/402,568

(22) Filed: Feb. 22, 2012

(30) Foreign Application Priority Data
Sep. 8, 2011 (CN) 201110266012.5

(51) Int. Cl. H05K 7/20

(52) U.S. Cl. 361/679.48; 361/679.46

(57) ABSTRACT

A server rack system including a rack is provided. The rack has a front end, a rear end, and a receiving portion. The bottom of the front end has an air inlet. The rear end has an air outlet. The receiving portion is disposed in the rack and is located between the front end and the rear end, so as to receive a plurality of server units. An air flow flows into the rack from the air inlet, vertically upward parallel to the front end, horizontally through the server units, and out the rear end in sequence.

### CROSS-REFERENCE TO RELATED APPLICATION

This application claims the priority benefit of China application serial no. 201110266012.5, filed Sep. 8, 2011. The entirety of the above-mentioned patent application is hereby incorporated by reference herein and made a part of this specification.

### BACKGROUND OF THE INVENTION

1. Field of the Invention

The present invention generally relates to a rack, and in particular, to a rack of a server.

2. Description of Related Art

A server is a core computer serving computers in a network system, may provide functions such as a magnetic disk and a print service required by a network user, and meanwhile may also be used for clients to share resources in a network environment with each other. The basic architecture of the server is approximately the same as that of a general personal computer, and is formed of components such as a Central Processing Unit (CPU), a memory and an Input/Output (I/O) apparatus, which are connected by a bus inside. The CPU and the memory are connected through a north bridge chip, and the I/O apparatus is connected to a south bridge chip. As far as a cabinet structure is concerned, servers have experienced three evolutionary stages: from an early tower cabinet server to a frame or rack server emphasizing centralized performance, and then to a blade server with a high density computation approach.

Herein, a frame server is taken as an example. The frame server is a server whose appearance is designed according to a uniform standard, and which is further uniformly used in cooperation with a rack. The frame server is a tower server having an optimized structure, the design aim of which is mainly to reduce space occupation of the server as much as possible. Many professional network apparatuses adopt the frame structure, and mostly are of a plat type just like a drawer, such as an exchanger, a router, and a hardware firewall. The width of the frame server is 19 inches, the unit of the height thereof is some multiple of U (1U=1.75 inches=44.45 millimeters), and generally there are several standard servers of 1U, 2U, 3U, 4U, 5U, and 7U.

As the operation speed of the server is continuously increased, heat generation produced by the electronic elements inside the server also rises. In order to prevent the electronic elements inside the server from being overheated to result in temporary or permanent failure, it is critical to provide sufficient heat dissipation performance to the electronic elements inside the server.

### SUMMARY OF THE INVENTION

Accordingly, the present invention is directed to a server rack system, which has a preferable internal layout to improve heat dissipation performance thereof.

An embodiment of the present invention provides a server rack system, which includes a rack. The rack includes a front end, a rear end and a receiving portion. The bottom of the front end has an air inlet. The rear end has an air outlet. The receiving portion is disposed in the rack and is located between the front end and the rear end, so as to receive a plurality of server units. An air flow sequentially flows into the rack from the air inlet, then parallel adjacent to the front end, then horizontally and in parallel through each of the server units, and then out of the rack from the air outlet at the rear end.

In an embodiment of the present invention, the rack further includes a cover, which is openably and closably mounted to the front end. When the cover is opened, the server units pass through the front end along a horizontal direction, and are mounted to the receiving portion or dismounted from the receiving portion. When the cover is closed, the cover restricts the air flow from flowing out of the rack other than through the rear end.

In an embodiment of the present invention, for each server unit, the receiving portion, the rear end and the air outlet jointly form a first flow passage. A second flow passage is formed between the cover and front plates of the server units. The first flow passages are in communication with the second flow passage, and each first flow passage flows through a server unit. The air flow passes through the second flow passage and then enters each of the server units from the front plates of the server units, and flows out from rear windows of the server units and enters the rear end, so as to dissipate heat of the server units.

In an embodiment of the present invention, the first flow passage is horizontally oriented, and the second flow passage is vertically oriented.

In an embodiment of the present invention, the front plate of the server unit and/or the rear window of the server unit have net structures.

In an embodiment of the present invention, the server rack system is disposed on a floor of a machine room, and the air inlet is disposed over an air feed opening on the floor of the machine room.

In an embodiment of the present invention, the server rack system further includes a fan wall, configured at the air outlet and covering the air outlet. The air flow is drawn from the rack through the fan wall. The fan wall comprises a plurality of fan modules arranged along a vertical direction.

In an embodiment of the present invention, each of the fan modules corresponds to a plurality of server units.

In an embodiment of the present invention, each of the fan modules includes a fan bracket and a plurality of fan units. The fan bracket is detachably mounted to the rear end of the rack. The plurality of fan units is detachably mounted to the fan bracket and arranged at the fan bracket along a horizontal direction.

In an embodiment of the present invention, the server rack system further includes a plurality of air vents, each air vent comprising a plurality of movable slats or blinds, in which the air vents are respectively mounted to one end of the fan brackets close to the interior of the rack. Each of the fan brackets has a plurality of openings, and the openings are respectively aligned with the fan units. The air vents respectively correspond to the openings. Each of the air vents is opened or closed to expose the corresponding opening or shield the corresponding opening.

In an embodiment of the present invention, the server rack system further includes a power transmission unit, disposed between the top and the bottom of the rear end along a vertical direction, and located in a gap formed between the first flow passage and the rack without blocking the first flow passage.

In an embodiment of the present invention, the server rack system further includes a line arrangement structure, disposed between the top and the bottom of the front end along a vertical direction, and located in a gap formed between the second flow passage and the rack without blocking the second flow passage.

Based on the above description, in the embodiment of the present invention, the server rack system, through the structure layout thereof, enables the air flow to flow into the rack from the air inlet at the bottom first, flow upwards along the front end of the rack, then horizontally through the server units and the rear end of the rack, all in sequence. Then the air flows out of the rack from the air outlet at the rear end during operation of the server units, thereby achieving optimal heat dissipation effect for electronic elements inside the server units.

In order to make the aforementioned features and advantages of the present invention more comprehensible, embodiments are illustrated in detail hereinafter with reference to the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B are schematic views of a server according to an embodiment of the present invention at different viewing angles respectively;

FIG. 2 is a schematic view of a part of components in the server in FIG. 1A or FIG. 1B,

FIG. 3 is a schematic view of air flowing in the server in FIG. 1A;

FIG. 4A and FIG. 4B are schematic views of a server unit in FIG. 2 at different viewing angles respectively; and

FIG. 5A and FIG. 5B are schematic views of fan units in the server in FIG. 2 in different states respectively.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

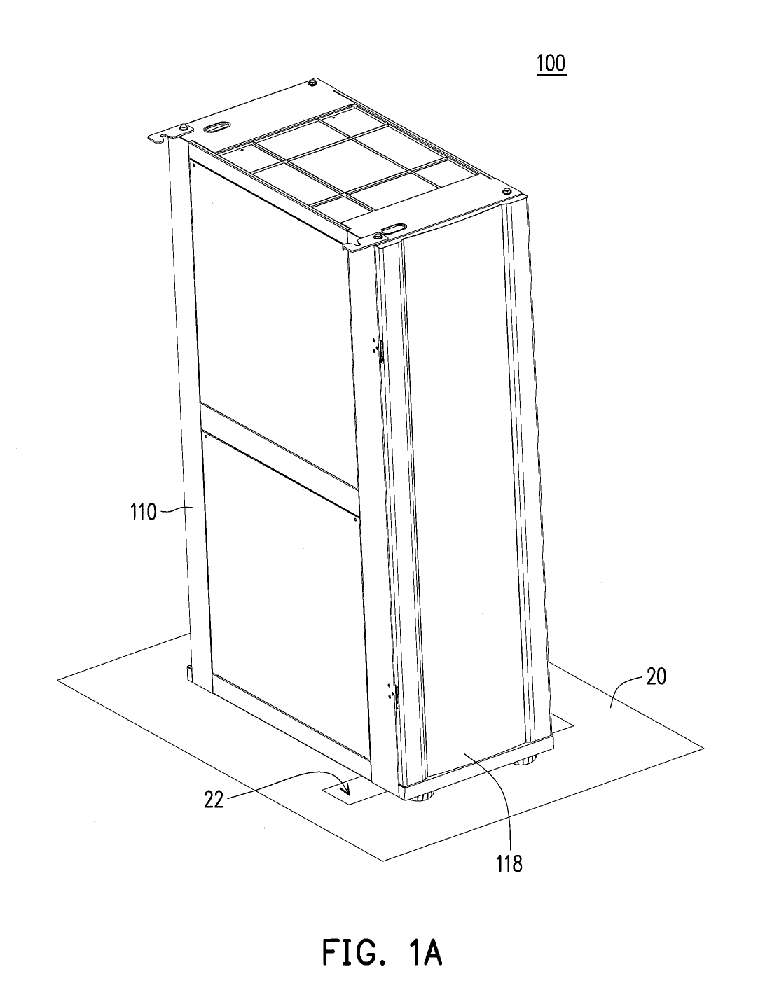

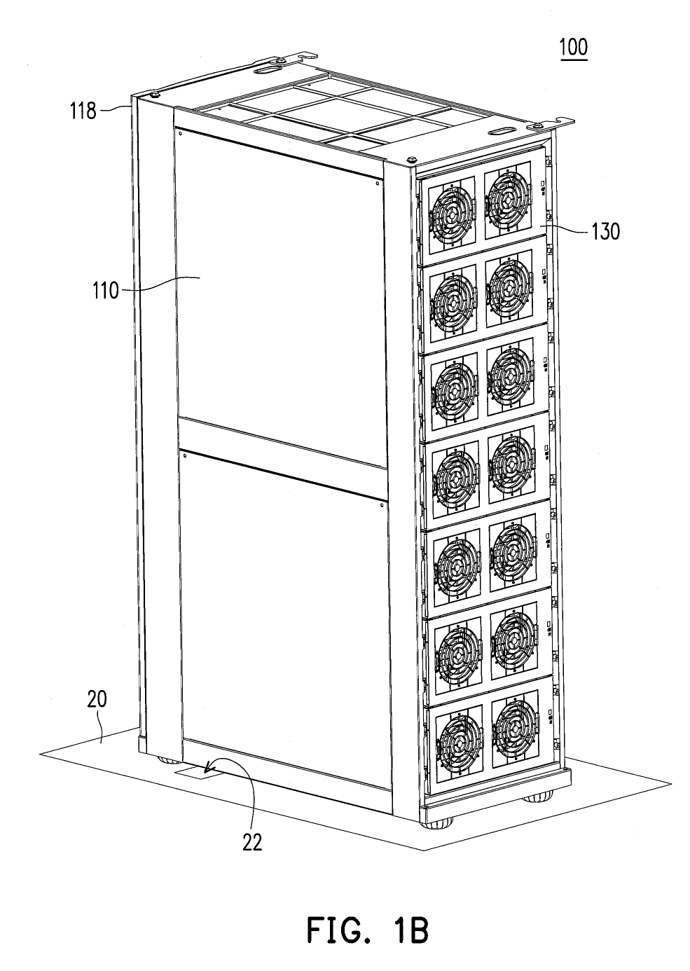

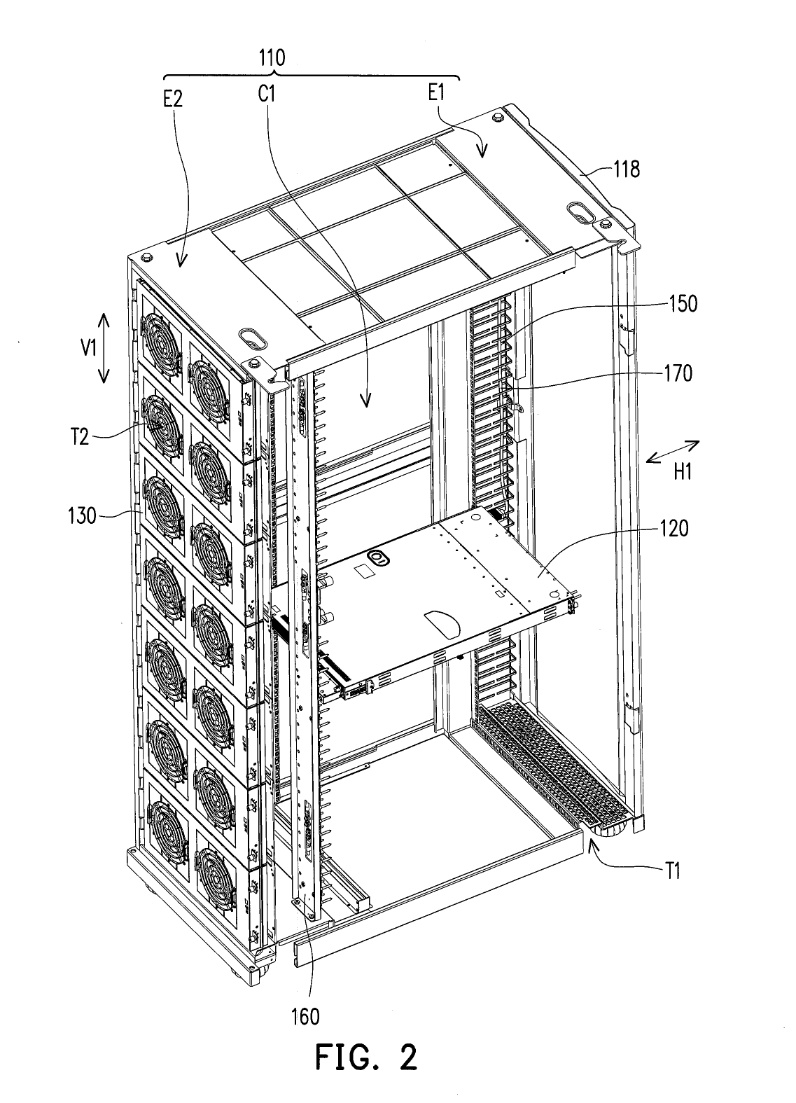

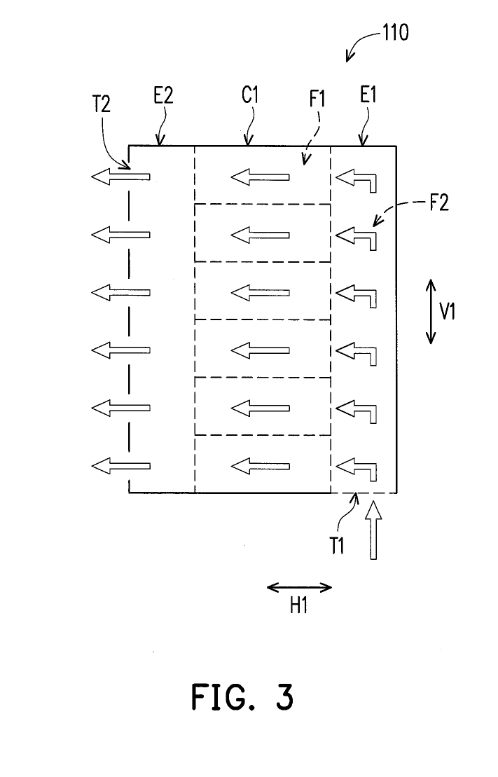

FIG. 1A and FIG. 1B are schematic views of a server rack system according to an embodiment of the present invention at different viewing angles respectively. FIG. 2 is a schematic view of a part of components in the server rack system in FIG. 1A or FIG. 1B. FIG. 3 is a schematic view of air flowing in the server rack system in FIG. 2. Referring to FIG. 1A, FIG. 1B, and FIG. 2 and FIG. 3, in this embodiment, a server rack system 100 includes a rack 110 and a plurality of server units 120, in which the server units 120 are detachably mounted to the rack 110 along a horizontal direction H1. Herein, only one server unit 120 is drawn as an example. The rack 110 has a front end E1, a rear end E2 and a receiving portion C1. The bottom of the front end E1 has an air inlet T1, and the rear end E2 has an air outlet T2. The receiving portion C1 is disposed in the rack 110 and located between the front end E1 and the rear end E2, and is used to receive the server unit 120.

In this embodiment, the server rack system 100 is disposed on a floor 20 of a machine room, and the air inlet T1 is disposed corresponding to an air feed opening 22 on the floor 20 of the machine room.

Therefore, an air flow flows into the rack 110 from the air inlet T1, flows through the front end E1, the server unit 120 and the rear end E2 in sequence, and then flows out of the rack 110 from the air outlet T2.

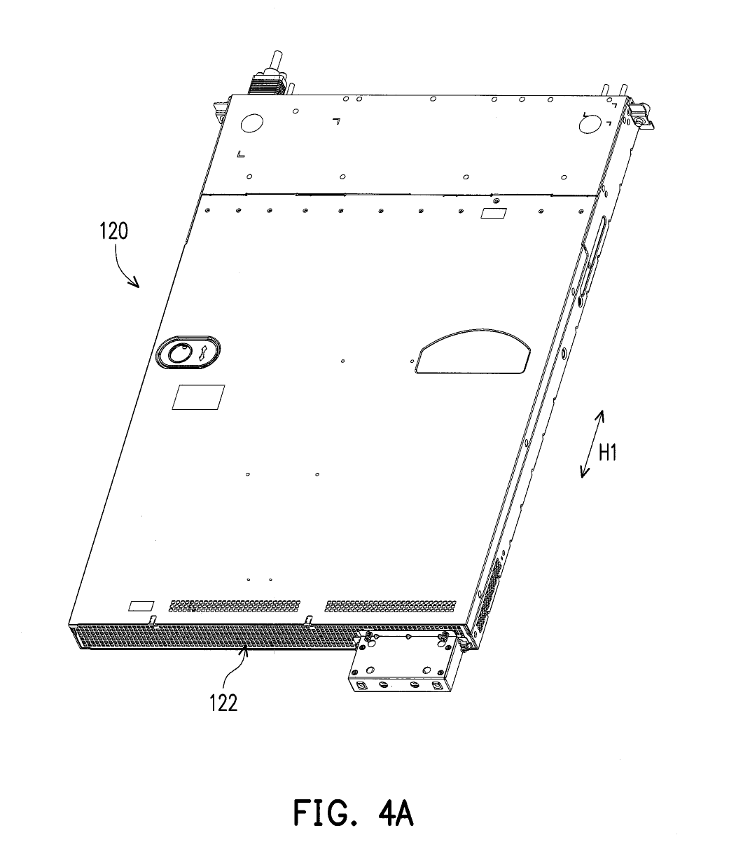

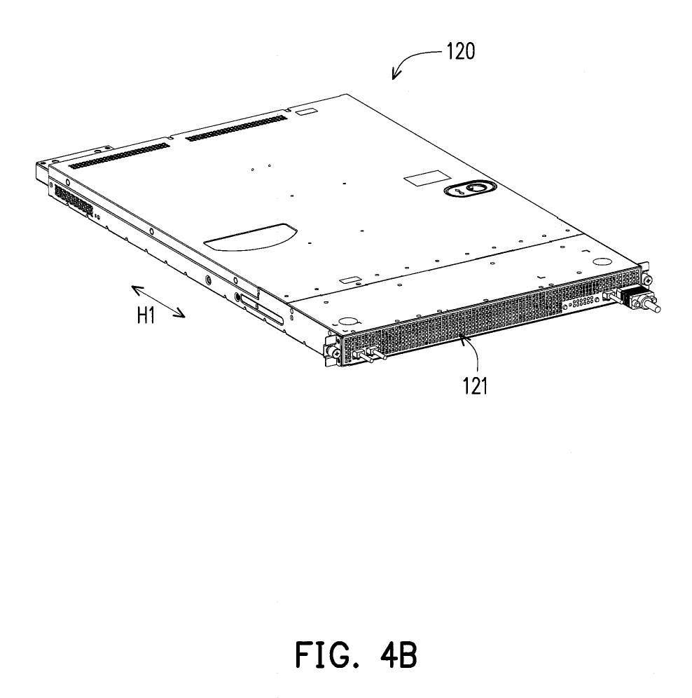

In this embodiment, the rack 110 further includes a cover 118, which is openably and closably mounted to the front end E1. When the cover 118 is opened, the server unit 120 passes through the front end E1 along a horizontal direction H1, and is mounted to the receiving portion C1 or dismounted from the receiving portion C1. When the cover 118 is closed, the cover 118 restricts the air flow from flowing out of the rack 110 other than through the rear end E2. Furthermore, the receiving portion C1, the rear end E2 and the air outlet T2 jointly form a first flow passage F1 for each server unit 120 mounted in the rack 110. A second flow passage F2 is formed between the cover 118 and the front plates 121 (FIG. 4B) of the server units 120. The first flow passages F1 are in communication with the common second flow passage F2, and each first flow passage F1 flows through a server unit 120. The air flow passes through the second flow passage F2 and then enters the server unit 120 from the front plate 121 of the server unit 120, and flows out from a rear window 122 of the server unit 120 and enters the rear end E2, so as to dissipate heat out of the server unit 120. Herein, the first flow passages F1 are in the horizontal direction H1, the second flow passage F2 is in a vertical direction V1, and the first flow passage F1 is substantially perpendicular to the second flow passage F2.

Moreover, FIG. 4A and FIG. 4B are schematic views of the server unit in FIG. 2 at different viewing angles respectively. It should be noted that, the front plate 121 of the server unit 120 and/or the rear window 122 of the server unit 120 are of a net or grid structure, so as to facilitate flowing of the air flow.

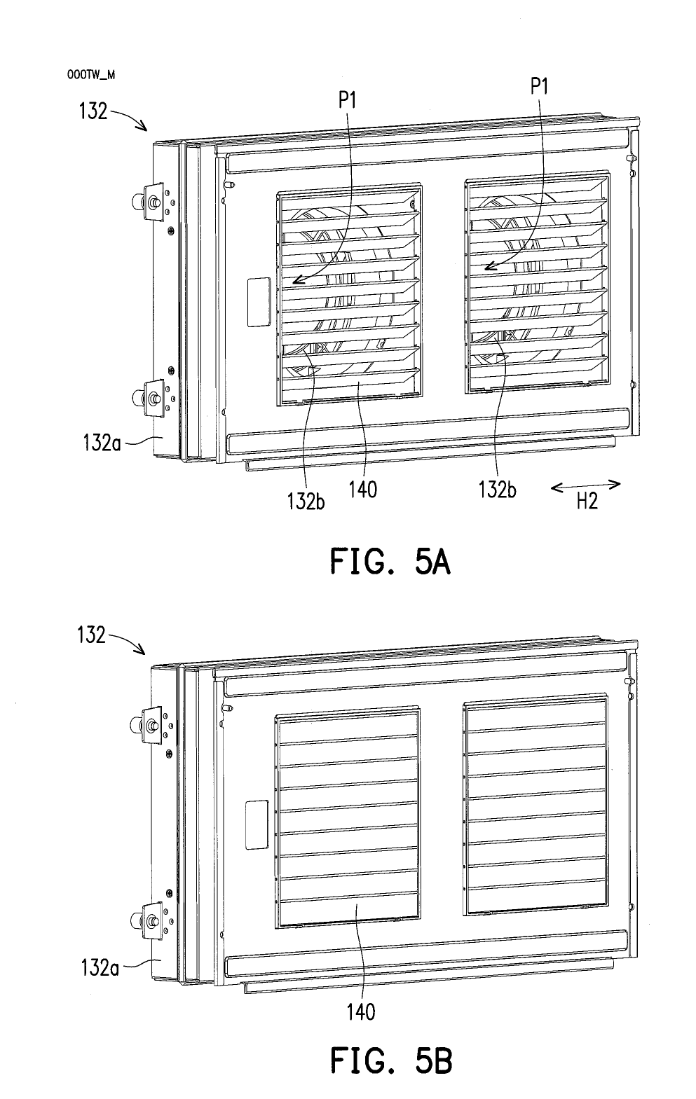

FIG. 5A and FIG. 5B are schematic views of fan units in the server in FIG. 2 in different states respectively. Referring to FIG. 2, FIG. 5A, and FIG. 5B, in this embodiment, the server rack system 100 further includes a fan wall 130, which is configured at the air outlet T2 and covers the air outlet T2. The air flow is drawn from the rack 110 by the fan wall 130. The fan wall 130 includes a plurality of fan modules 132, and the fan modules 132 are arranged along the vertical direction V1. Furthermore, each fan module 132 may correspond to a plurality of server units 120, so as to facilitate heat dissipation of the server unit 120. Each fan module 132 includes a fan bracket 132a and two fan units 132b. The fan bracket 132a is detachably mounted to the rear end E2 of the rack 110. The fan units 132b are detachably mounted to the fan bracket 132a and are arranged at the fan bracket 132a along a horizontal direction H2.

Moreover, the server rack system 100 further includes a plurality of air vent structures 140, and the air vent structures 140 are respectively mounted to one end of the fan brackets 132a close to the interior of the rack 110. Each air vent structure comprises at least one, and preferably a plurality of, pivotally coupled, movable covering plates, slats or blinds that are disposed by negative air pressure produced by the corresponding fan to open, and if the fan is closed, disposed by gravity to close shut. Each fan bracket 132a has a plurality of openings P1, the openings P1 are respectively aligned with the fan units 132b, the air vent structures 140 respectively correspond to the openings P1, and each air vent structure 140 is opened or closed to expose the corresponding opening P1 or shield the corresponding opening P1.

Referring to FIG. 2 again, in this embodiment, the server rack system 100 further includes a power transmission unit 160 and a line arrangement structure 150. The power transmission unit 160 is disposed between the top and the bottom of the rear end E2 along the vertical direction V1, and located in a gap formed between the first flow passage F1 (referring to FIG. 3) and the rack 110 without blocking the first flow passage F1. The line arrangement structure 150 is disposed between the top and the bottom of the front end E1 along the vertical direction V1, and located in a gap formed between the second flow passage F2 (referring to FIG. 3) and the rack 110 without blocking the second flow passage F2. The power transmission unit 160 is used to transfer power from a power supply (not shown) to the server unit 120 located at the receiving portion C1, and the line arrangement structure 150 is used to receive various cables 170 connected to the server unit 120 so as to be electrically connected to an external device (not shown). Based on the above description, the power transmission unit 160 and the line arrangement structure 150 are configured in the rack 110 in a manner that the two are not located on the first flow passage F1 and the second flow passage F2 respectively, so that the air flow can flow in the rack 110 without being blocked, thereby improving heat dissipation effect for the server unit 120.

In conclusion, in the embodiment of the present invention, the server rack system, through the structure layout of the rack thereof, enables the air flow to flow into the second flow passage from the air inlet at the bottom of the front end, branch at the first flow passage along the transverse axis, and flow out of the rack from the air outlet located at the rear end of the rack in sequence during operation of the server unit, thereby completely achieving the heat dissipation effect for the server unit in the receiving portion of the rack.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A server rack system for receiving a plurality of server units, comprising:
a rack, comprising:
a front end, the bottom of which comprises an air inlet;
a rear end comprising an air outlet; and
a receiving portion, disposed in the rack and located between the front end and the rear end, for receiving the server units, wherein an air flow sequentially flows into the rack from the air inlet, then vertically adjacent the front end, then horizontally and in parallel through each of the server units, and then out of the rack from the air outlet at the rear end.

2. The server rack system according to claim 1, wherein the rack further comprises:
a cover, openably and closably mounted to the front end, wherein when the cover is opened, the server units pass through the front end along a horizontal direction, and are mounted to the receiving portion or dismounted from the receiving portion; and when the cover is closed, the cover restricts the air flow from flowing out of the rack other than through the rear end.

3. The server rack system according to claim 2, wherein for each server unit, the receiving portion, the rear end and the air outlet jointly form a first flow passage, a second flow passage is formed between the cover and front plates of the server units, the first flow passages are in communication with the second flow passage, and each first flow passage F1 flows through a server unit; wherein the air flow passes through the second flow passage and then enters each of the server units from the front plates of the server units, and flows out from rear windows of the server units and enters the rear end, so as to dissipate heat of the server units.

4. The server rack system according to claim 3, wherein the first flow passage is horizontally oriented, and the second flow passage is vertically oriented.

5. The server rack system according to claim 3, wherein the front plate of the server unit and/or the rear window of the server unit have net structures.

6. The server rack system according to claim 1, wherein the server rack system is disposed on a floor of a machine room, and the air inlet is disposed over an air feed opening on the floor of the machine room.

7. The server rack system according to claim 1, further comprising:
a fan wall, configured at the air outlet and covering the air outlet, wherein the air flow is drawn from the rack through the fan wall, wherein the fan wall comprises a plurality of fan modules arranged along a vertical direction.

8. The server rack system according to claim 7, wherein each of the fan modules corresponds to a plurality of server units.

9. The server rack system according to claim 6, wherein each of the fan modules comprises:
a fan bracket, detachably mounted to the rear end of the rack; and
a plurality of fan units, detachably mounted to the fan bracket and arranged at the fan bracket along a horizontal direction.

10. The server rack system according to claim 9, further comprising a plurality of air vents, each air vent comprising a plurality of movable slats, wherein the air vents are respectively mounted to one end of the fan brackets close to the interior of the rack, wherein each of the fan brackets comprises a plurality of openings, the openings are respectively aligned with the fan units, the air vents respectively correspond to the openings, and each of the air vents is opened or closed to expose the corresponding opening or shield the corresponding opening.

11. The server rack system according to claim 3, further comprising:
a power transmission unit, disposed between the top and the bottom of the rear end along a vertical direction, and located in a gap formed between the first flow passage and the rack without blocking the first flow passage.

12. The server rack system according to claim 3, further comprising:
a line arrangement structure, disposed between the top and the bottom of the front end along a vertical direction, and located in a gap formed between the second flow passage and the rack without blocking the second flow passage.
